(19) United States
(12) Patent Application Publication
(10) Pub. No.: US 2024/0272494 A1
(43) Pub. Date: Aug. 15, 2024

(54) DISPLAY PANEL AND MANUFACTURING METHOD THEREOF

(71) Applicants: Beijing BOE Optoelectronics Technology Co., Ltd., Beijing (CN); BOE Technology Group Co., Ltd., Beijing (CN)

(72) Inventors: Xueyong ZHAI, Beijing (CN); Yao BI, Beijing (CN); Kangdi ZHOU, Beijing (CN); Donghua ZHANG, Beijing (CN); Jin GAO, Beijing (CN); Ce WANG, Beijing (CN); Xiaodong WANG, Beijing (CN); Jian WANG, Beijing (CN); Xingxing GUAN, Beijing (CN); Hongsheng BI, Beijing (CN)

(73) Assignees: Beijing BOE Optoelectronics Technology Co., Ltd., Beijing (CN); BOE Technology Group Co., Ltd., Beijing (CN)

(21) Appl. No.: 18/641,712

(22) Filed: Apr. 22, 2024

Related U.S. Application Data
(63) Continuation of application No. PCT/CN2022/127880, filed on Oct. 27, 2022.

(51) Int. Cl. G02F 1/1343; G02F 1/1335

(52) U.S. Cl. CPC G02F 1/134345; G02F 1/133512; G02F 2201/56; G02F 2203/30

(57) ABSTRACT

The present disclosure provides a display panel and a manufacturing method thereof. The display panel includes a special-shaped display region. The display panel further includes a base substrate and a plurality of pixels on a side of the base substrate, and the plurality of pixels includes an edge pixel with an orthographic projection on the base substrate overlapped with that of an edge of the special-shaped display region on the base substrate. The edge pixel is provided with a light-shielding pattern that divides the edge pixel into a light-shielding region and a light-transmitting region. The edge pixel has a predetermined gray scale and a brightness ratio, the brightness ratio is a ratio of a brightness of the light-transmitting region to a brightness of the edge pixel when an entire region thereof is light-transmitting, and the predetermined gray scale has an exponential function relationship with the brightness ratio.

### CROSS-REFERENCE TO RELATED APPLICATION

The present application is a continuation of International Application No. PCT/CN2022/127880, filed on Oct. 27, 2022, the entire disclosure of which is hereby incorporated by reference.

### TECHNICAL FIELD

The present disclosure relates to the field of display technology, and specifically, to a display panel and a manufacturing method thereof, and a display device.

### BACKGROUND

With the wide application of display screens in smart wearable devices and other portable electronic devices, the special-shaped display screens gradually become popular in consumers. The special-shaped display screens broaden the application range of the display screens, which can meet people's further requirements for displays, such as watches, wearable mobile phones or the like. Therefore, the special-shaped display screens currently become one of the search hotspots in the field of display technology.

The main difference of the special-shaped display screen from a conventional display screen is that the display region thereof has a special non-rectangular shape. Generally speaking, the pixels in the display screen are mostly rectangular or other relatively regular structures, so when the pixels are applied to the special-shaped display screen, in the edge region of the display screen, the boundary line of the display screen cannot be fully coincident with the pixels, which will result the presence of zigzag lines on the edge region of the display screen upon displaying.

It is to be noted that the information disclosed in the above background section is only used to enhance the understanding of the background of the present disclosure, and thus may include information that does not constitute the prior art known to those skilled in the art.

### SUMMARY

The present disclosure provides a display panel and a manufacturing method thereof, and a display device

A first aspect of the present disclosure provides a display panel. The display panel includes a display region and a non-display region at a periphery of the display region, the display region includes a main display region and a special-shaped display region at a periphery of the main display region;
the display panel further includes a base substrate and a plurality of pixels provided on a side of the base substrate, the plurality of pixels are provided in the display region, and the plurality of pixels includes an edge pixel with an orthographic projection on the base substrate overlapped with an orthographic projection of an edge of the special-shaped display region on the base substrate;
the edge pixel is provided with a light-shielding pattern, and the light-shielding pattern divides the edge pixel into a light-shielding region and a light-transmitting region; and
the edge pixel has a predetermined gray scale and a brightness ratio, the brightness ratio is a ratio of a brightness of the light-transmitting region of the edge pixel to a brightness of the edge pixel when an entire region of the edge pixel is light-transmitting, and the predetermined gray scale of the edge pixel has an exponential function relationship with the brightness ratio of the edge pixel.

In an embodiment of the present disclosure, the pixel includes a plurality of sub-pixels spaced apart in a first direction, and the light-shielding pattern includes a plurality of light-shielding sub-patterns arranged in the first direction and respectively corresponding to the sub-pixels of the edge pixel;
the light-shielding sub-pattern has a first dividing edge, the first dividing edge divides the sub-pixel into a light-shielding sub-region and a light-transmitting sub-region, the first dividing edge has a first angle α1 with respect to the first direction, and 0≤α1≤90°;
the edge of the special-shaped display region intersects with edges of the edge pixel at a first intersection point and a second intersection point, and a line connecting the first intersection point and the second intersection point is a first connecting line; and
the first dividing edge is inclined in a same direction as the first connecting line.

In an embodiment of the present disclosure, the first connecting line has a second angle with respect to the first direction, and a difference between the first angle and the second angle is not greater than 2°.

In an embodiment of the present disclosure, the first angle and the second angle are equal to each other.

In an embodiment of the present disclosure, the edge of the special-shaped display region has a start point and an end point, and in a direction from the start point to the end point of the edge of the special-shaped display region, a difference between the first angles of the light-shielding sub-patterns of two adjacent edge pixels is b;
a number of edge pixels corresponding to the edge of the special-shaped display region is n; and
the edge of the special-shaped display region has an approximate angle β, the approximate angle is a corresponding central angle of a circular arc when the edge of the special-shaped display region is fitted into the circular arc, and
b=β/n.

In an embodiment of the present disclosure, the edge of the special-shaped display region has a start point and an end point, and in a direction from the start point to the end point of the edge of the special-shaped display region, a difference between the first angles of the light-shielding sub-patterns of two adjacent edge pixels is b, and
b=90°/m
where m is a number of corresponding edge pixels when the edge of the special-shaped display region is fitted and expanded into a ¼ circular arc.

In an embodiment of the present disclosure, the first angles of the light-shielding sub-patterns corresponding to respective sub-pixels in a single pixel are equal to each other.

In an embodiment of the present disclosure, the predetermined gray scale of the edge pixel satisfies a following relationship with the brightness ratio of the edge pixel:

$$G y = k \times {( \frac{M}{N} )}^{( \frac{1}{h} )}$$

where Gy is the predetermined gray scale of the edge pixel, M is the brightness of the light-transmitting region of the edge pixel, N is the brightness of the edge pixel when the entire region of the edge pixel is light-transmitting, k is a first constant, and h is a gamma value.

In an embodiment of the present disclosure, k has a value of 255 and h has a value of 2.2.

In an embodiment of the present disclosure, the edge of the special-shaped display region divides a corresponding edge pixel into a display sub-region and a non-display sub-region, wherein an area of the entire region of the edge pixel is A0, an area of the display sub-region of the edge pixel is A1, an area of the non-display sub-region of the edge pixel is A2, A1+A2=A0, and

$$G y = 255 \times {( \frac{A 1}{A 0} )}^{( \frac{1}{h} )}$$

where Gy is the predetermined gray scale of the edge pixel, and h is a gamma value.

A second aspect of the present disclosure provides a manufacturing method of a display panel, the display panel including a display region and a non-display region at a periphery of the display region, the display region including a main display region and a special-shaped display region at a periphery of the main display region, wherein the manufacturing method includes:
providing a base substrate;
forming a plurality of pixels on a side of the base substrate, the plurality of pixels being provided in the display region, the plurality of pixels including an edge pixel with an orthographic projection on the base substrate overlapped with an orthographic projection of an edge of the special-shaped display region on the base substrate, the edge pixel being provided with a light-shielding pattern, the light-shielding pattern dividing the edge pixel into a light-shielding region and a light-transmitting region, and the edge pixel having an experimental gray scale;
setting a predetermined gray scale for the edge pixel; and
adjusting a size of the light-shielding pattern to change a brightness ratio and the experimental gray scale of the edge pixel such that the experimental gray scale of the edge pixel is equal to the predetermined gray scale of the edge pixel,
wherein the brightness ratio is a ratio of a brightness of the light-transmitting region of the edge pixel to a brightness of the edge pixel when an entire region of the edge pixel is light-transmitting, and the experimental gray scale of the edge pixel has an exponential function relationship with the brightness ratio of the edge pixel.

In an embodiment of the present disclosure, the pixel includes a plurality of sub-pixels spaced apart in a first direction, and the light-shielding pattern includes a plurality of light-shielding sub-patterns arranged in the first direction and respectively corresponding to the sub-pixels of the edge pixel;
the light-shielding sub-pattern has a first dividing edge, the first dividing edge divides the sub-pixel into a light-shielding sub-region and a light-transmitting sub-region, the first dividing edge has a first angle α1 with respect to the first direction, and 0≤α1≤90°;
the edge of the special-shaped display region intersects with edges of the edge pixel at a first intersection point and a second intersection point, and a line connecting the first intersection point and the second intersection point is a first connecting line; and
the first dividing edge is inclined in a same direction as the first connecting line.

In an embodiment of the present disclosure, the first connecting line has a second angle with respect to the first direction, and a difference between the first angle and the second angle is not greater than 2°.

In an embodiment of the present disclosure, the first angle and the second angle are equal to each other.

In an embodiment of the present disclosure, the edge of the special-shaped display region has a start point and an end point, and in a direction from the start point to the end point of the edge of the special-shaped display region, a difference between the first angles of the light-shielding sub-patterns of two adjacent edge pixels is b;
a number of edge pixels corresponding to the edge of the special-shaped display region is n; and
the edge of the special-shaped display region has an approximate angle β, the approximate angle is a corresponding central angle of a circular arc when the edge of the special-shaped display region is fitted into the circular arc, and

$$b = β / n .$$

In an embodiment of the present disclosure, the edge of the special-shaped display region has a start point and an end point, and in a direction from the start point to the end point of the edge of the special-shaped display region, a difference between the first angles of the light-shielding sub-patterns of two adjacent edge pixels is b, and

$$b = 90 ° / m$$

where m is a number of corresponding edge pixels when the edge of the special-shaped display region is fitted and expanded into a ¼ circular arc.

In an embodiment of the present disclosure, the first angles of the light-shielding sub-patterns corresponding to respective sub-pixels in a single pixel are equal to each other.

In an embodiment of the present disclosure, the light-shielding sub-pattern has a design length in a third direction, the third direction has a third angle with respect to the first direction, and the third angle is greater than the first angle; and
adjusting the size of the light-shielding pattern includes:
changing a size of a corresponding light-shielding pattern by adjusting a design length of the light-shielding sub-pattern to adjust a size of the light-shielding sub-pattern.

In an embodiment of the present disclosure, the experimental gray scale of the edge pixel satisfies a following relationship with the brightness ratio of the edge pixel:

$${Gy}^{′} = k \times {( \frac{M}{N} )}^{( \frac{1}{h} )}$$

where Gy′ is the experimental gray scale of the edge pixel, M is the brightness of the light-transmitting region of the edge pixel, N is the brightness of the edge pixel when the entire region of the edge pixel is light-transmitting, k is a first constant, and h is a gamma value.

In an embodiment of the present disclosure, the edge of the special-shaped display region divides a corresponding edge pixel into a display sub-region and a non-display sub-region, an area of the entire region of the edge pixel is A0, an area of the display sub-region of the edge pixel is A1, an area of the non-display sub-region of the edge pixel is A2, A1+A2=A0, and

$$G y = 255 \times {( \frac{A 1}{A 0} )}^{( \frac{1}{h} )}$$

where Gy is the predetermined gray scale of the edge pixel, and h is a gamma value.

A third aspect of the present disclosure provides a display device including the display panel as described in the first aspect.

### BRIEF DESCRIPTION OF THE DRAWINGS

The foregoing and other features and advantages of the present disclosure will become more apparent by describing the example embodiments thereof in detail with reference to the accompanying drawings.

FIG. 1 is a schematic diagram of a planar structure of a display panel in an embodiment of the present disclosure;

FIG. 2 is a schematic diagram of a structure of a portion of a special-shaped display region in an embodiment of the present disclosure;

FIG. 3 is a schematic diagram of a structure in which an edge pixel is divided by a special-shaped display region in an embodiment of the present disclosure;

FIG. 4 is a schematic diagram of a structure of a light-shielding pattern in an embodiment of the present disclosure;

FIG. 5 is a schematic diagram of a structure of an approximate angle of an edge of a special-shaped display region in an embodiment of the present disclosure;

FIG. 6 is a schematic diagram of an L255 picture brightness distribution of a pixel in an embodiment of the present disclosure; and

FIG. 7 is a schematic diagram of a structure of a designed length of a light-shielding pattern in an embodiment of the present disclosure.

### DETAILED DESCRIPTION

Example embodiments will now be described more fully with reference to the accompanying drawings. However, the example embodiments may be implemented in a variety of forms and should not be construed as being limited to examples set forth herein; rather, these embodiments are provided so that the present disclosure is more comprehensive and complete and the concept of the example embodiments is conveyed to a person skilled in the art in a comprehensive manner. The described features, structures, or characteristics may be combined in one or more embodiments in any suitable manner. In the following description, many specific details are provided to give a full understanding of the embodiments of the present disclosure.

In the figures, the thickness of a region and a layer may be exaggerated for clarity. The same reference numerals in the drawings denote the same or similar structures, and thus their detailed descriptions will be omitted.

The features, structures or characteristics described may be combined in one or more embodiments in any suitable manner. In the following description, many specific details are provided to give a full understanding of the embodiments of the present disclosure. However, a person skilled in the art may realize that the technical solution of the present disclosure may be practiced without one or more particular details described, or may be practiced by employing other methods, components, materials, or the like. In other cases, common known structures, materials, or operations are not shown or described in detail to avoid obscuring the main technical ideas of the present disclosure.

When a structure is “on” another structure, it may mean that the structure is integrally formed on another structure, or that the structure is “directly” provided on another structure, or that the structure is “indirectly” provided on another structure through an additional structure.

The terms “a”, “an” and “the” are used to indicate the presence of one or more elements/components/etc.; and the terms “comprising/including” and “having” are used to indicate open-ended inclusion and mean that there may be additional elements/components/etc. in addition to those listed. The terms “first”, “second” or the like are used only as markers without limiting the number of objects thereof.

A special-shaped display screen typically includes a main display region, i.e., a normal display region, in the center thereof, and a special-shaped display region located at the periphery of the main display region. In the related art, a pixel in the special-shaped display region is designed to be partially shieled so as to eliminate undesirable zigzags presented on the edge of the special-shaped display region upon displaying, however such shielding design is not precise enough to meet the requirements of high PPI (pixels per inch, which is a pixel density unit) display products.

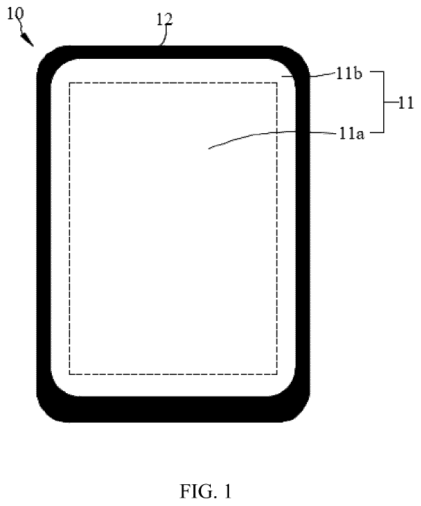

As shown in FIGS. 1, 2, and 4, an embodiment of the present disclosure provides a display panel 10 including a display region 11 and a non-display region 12 provided at the periphery of the display region 11, and the display region 11 includes a main display region 11a and a special-shaped display region 11b provided at the periphery of the main display region 11a.

The display panel 10 further includes a base substrate and a plurality of pixels 20 provided on a side of the base substrate, and the pixels 20 are provided in the display region 11. The plurality of pixels 20 include an edge pixel 21 with an orthographic projection on the base substrate overlapped with an orthographic projection of an edge L1 of the special-shaped display region 11b on the base substrate. The edge pixel 21 is provided with a light-shielding pattern 30, and the light-shielding pattern 30 divides the edge pixel 21 into a light-shielding region 211 and a light-transmitting region 212. The edge pixel 21 has a predetermined gray scale and a brightness ratio, the brightness ratio is a ratio of a brightness of the light-transmitting region 212 of the edge pixel 21 to a brightness of the edge pixel 21 when an entire region of the edge pixel 21 is light-transmitting, and the predetermined gray scale of the edge pixel 21 has an exponential function relationship with the brightness ratio of the edge pixel 21.

In the display panel 10 provided by the present disclosure, the edge pixel 21 is provided with the light-shielding pattern 30, and the light-shielding pattern 30 divides the edge pixel 21 into the light-shielding region 211 and the light-transmitting region 212. The edge pixel 21 has the predetermined gray scale and the brightness ratio, the brightness ratio is the ratio of the brightness of the light-transmitting region 212 of the edge pixel 21 to the brightness of the edge pixel 21 when the entire region of the edge pixel 21 is light-transmitting, and the predetermined gray scale of the edge pixel 21 has an exponential function relationship with the brightness ratio of the edge pixel 21. In the present disclosure, a correspondence is established between the brightness of the light-transmitting region 212 of the edge pixel 21 and the predetermined gray scale of the edge pixel 21, which manner comprehensively considers the case where the pixel 20 has different display brightnesses in different regions, and thus can enhance the uniformity of the gray scale transition between the regions at both sides of the edge pixel 21, thereby attenuating the problem of the presence of zigzags on the edge of the special-shaped display region 11b upon displaying, and thus improving the display quality of the display panel 10.

The components of the display panel 10 provided by the embodiment of the present disclosure are described in detail below in conjunction with the accompanying drawings.

As shown in FIG. 1, the present disclosure provides a display panel 10, which may be a liquid crystal display (LCD) panel 10. The display panel 10 includes a display region 11 and a non-display region 12 provided at the periphery of the display region 11. The display region 11 includes a main display region 11a and a special-shaped display region 11b provided at the periphery of the main display region 11a.

The display region 11 is used to display a picture, and the main display region 11a is located in the middle part of the display region 11. The special-shaped display region 11b is located at the periphery of the main display region 11a, and the edge L1 of the special-shaped display region 11b may be circular, arc-shaped, curved, or the like, which is specifically determined according to the actual application requirements of the display panel 10.

As shown in FIGS. 1, 2, and 4, the display panel 10 includes a base substrate and a plurality of pixels 20 provided on a side of the base substrate, and the pixels 20 are provided in the display region 11. The base substrate may be a glass substrate, a flexible substrate or the like, such as a polyimide flexible substrate. The plurality of pixels 20 are spaced apart, in particular, the plurality of pixels 20 may be arranged in an array in a first direction X and a second direction Y. There is a certain angle between the first direction X and the second direction Y, which may be any angle from 0° to 90°. For example, the angle between the first direction X and the second direction Y is substantially 90°.

The plurality of pixels 20 may be divided by a black matrix 31, and the black matrix 31 is formed from a light-shielding material such as a black resin material. Each pixel 20 includes a plurality of sub-pixels 201 spaced apart in the first direction X. Respective sub-pixel 201 may respectively emit different colors of light. By way of example, each pixel 20 includes three sub-pixels 201, which respectively are a red sub-pixel 201, a green sub-pixel 201 and a blue sub-pixel 201 arranged sequentially in the first direction X. The sub-pixels 201 of the pixel 20 are divided from each other by the black matrix 31.

The plurality of pixels 20 include an edge pixel 21 with an orthographic projection on the base substrate overlapped with an orthographic projection of the edge L1 of the special-shaped display region 11b on the base substrate. That is, the pixel 20 corresponding to the edge L1 of the special-shaped display region 11b in a direction perpendicular to the base substrate is the edge pixel 21. The number of edge pixels 21 may be determined according to the shape or length of the edge L1 of the special-shaped display region 11b.

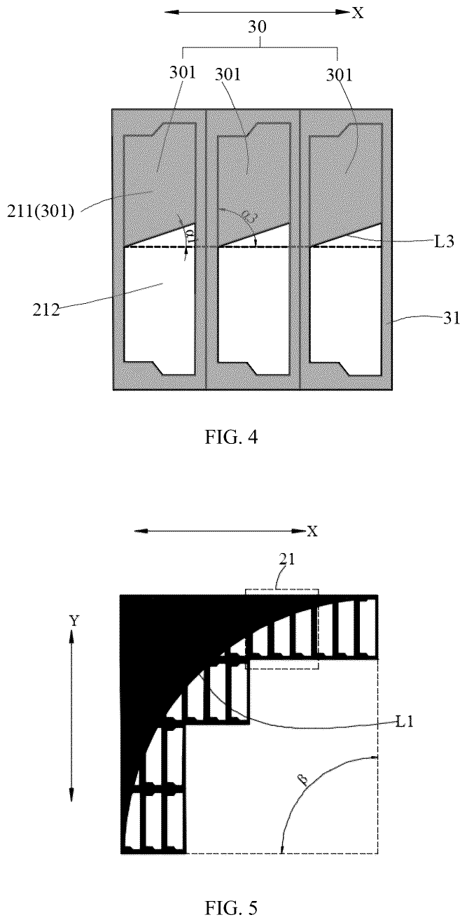

The edge pixel 21 is provided with a light-shielding pattern 30, and the light-shielding pattern 30 divides the edge pixel 21 into a light-shielding region 211 and a light-transmitting region 212. The light-shielding pattern 30 may be provided in the same layer as the black matrix 31, i.e., they are made of the same material and are prepared in the same process. In FIG. 4, the filling patterns of the light-shielding pattern 30 and the black matrix 31 are made transparent in order to clearly show the shape of the light-shielding pattern 30. The light-transmitting region 212 of the edge pixel 21 may be used for displaying and the light-shielding region 211 may not be used for displaying. It is to be noted herein that in the present disclosure, all regions of the pixels 20 other than the edge pixels 21 may be light-transmitting regions, and within the main display region 11a, all regions of respective sub-pixels 201 of each pixel 20 are light-transmitting regions, and may be used for displaying. All regions of respective sub-pixel 201 of each of the pixels 20 other than the edge pixels 21 within the special-shaped display region 11b are also light-transmitting regions 212, and may be used for displaying.

In some embodiments of the present disclosure, the edge pixel 21 has a predetermined gray scale. The predetermined gray scale of the edge pixel 21 is set according to the areas of the two regions of the edge pixel 21 after being divided by the edge L1 of the special-shaped display region 11b, so that the predetermined gray scale of the edge pixel 21 may achieve uniform gray scale transition between the regions at both sides of the edge L1 of the special-shaped display region 11b.

As shown in FIG. 3, by way of example, the edge L1 of the special-shaped display region 11b divides a corresponding edge pixel 21 into a display sub-region 213 and a non-display sub-region 214, the area of the entire region of the edge pixel 21 is A0, the area of the display sub-region 213 of the edge pixel 21 is A1, the area of the non-display sub-region 213 of the edge pixel 21 is A2, and A1+A2=A0. Further, the predetermined gray scale of the edge pixel 21 is set according to a ratio of the area A1 of the display sub-region 213 to the area A0 of the entire region of the edge pixel 21. The gray scale represents a brightness level of the pixel 20, and currently, 0˜255 gray scales are generally divided in the display industry by taking an 8 bit Panel as the benchmark, and there are a total of 256 brightness levels. As defined, when A1=A0, the gray scale of the edge pixel 21 is 255, and when A1=0, the gray scale of the edge pixel 21 is 0. In a specific embodiment, the predetermined gray scale of the edge pixel 21 satisfies the following relationship:

$$G y = 255 \times {( \frac{A 1}{A 0} )}^{( \frac{1}{h} )}$$

where Gy is the predetermined gray scale of the edge pixel 21, and h is a gamma value, which generally takes a value of 2.2.

The edge pixel 21 further has a brightness ratio, the brightness ratio is a ratio of a brightness of the light-transmitting region 212 of the edge pixel 21 to a brightness of the edge pixel 21 when an entire region of the edge pixel 21 is light-transmitting, and the predetermined gray scale of the edge pixel 21 has an exponential function relationship with the brightness ratio of the edge pixel 21. The brightness ratio of the edge pixel 21 is the base of the exponential function and the predetermined gray scale of the edge pixel 21 is a function value.

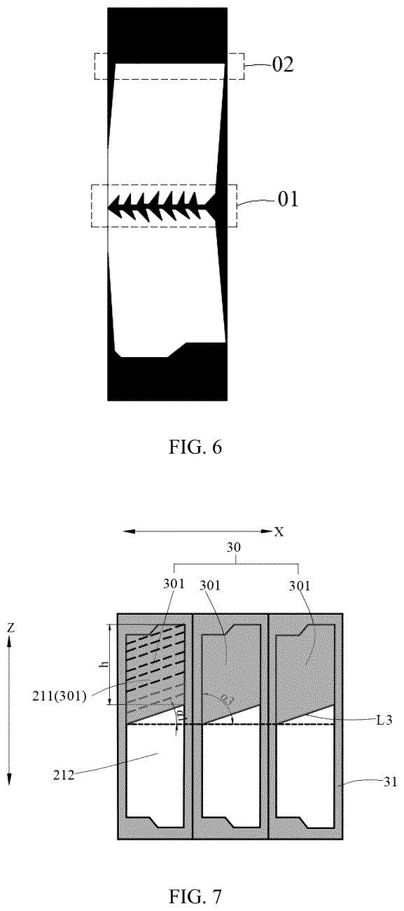

In the present disclosure, the brightness when the entire region of the edge pixel 21 is light-transmitting is defined as the L255 picture brightness. The L255 picture is an all-white picture. As shown in FIG. 6, in an actual display, the display brightnesses at different locations of the light-transmitting region of the pixel 20 are different. In FIG. 6, when the entire region of a pixel 20 is light-transmitting (L255 picture), the middle region 01 and the region 02 near the black matrix 31 of the pixel 20 are relatively dark and are of uneven brightness. The present disclosure takes this situation into account and establishes a correspondence between the ratio of the brightness of the light-transmitting region 212 of the edge pixel 21 to the brightness of the edge pixel 21 when the entire region of the edge pixel 21 is light-transmitting and the predetermined gray scale of the edge pixel 21, which can make the actual gray scale of the edge pixel 21 more accurately approximate the predetermined gray scale, and can enhance the uniformity of the gray scale transition between the regions at both sides of the edge pixel 21.

Further, the predetermined gray scale of the edge pixel 21 and the brightness ratio of the edge pixel 21 satisfy the following relationship:

$$G y = k \times {( \frac{M}{N} )}^{( \frac{1}{h} )}$$

where Gy is the predetermined gray scale of the edge pixel 21, M is the brightness of the light-transmitting region of the edge pixel 21, N is the brightness of the edge pixel 21 when the entire region of the edge pixel 21 is light-transmitting, k is a first constant that may be 255, and h is a gamma value that may be 2.2.

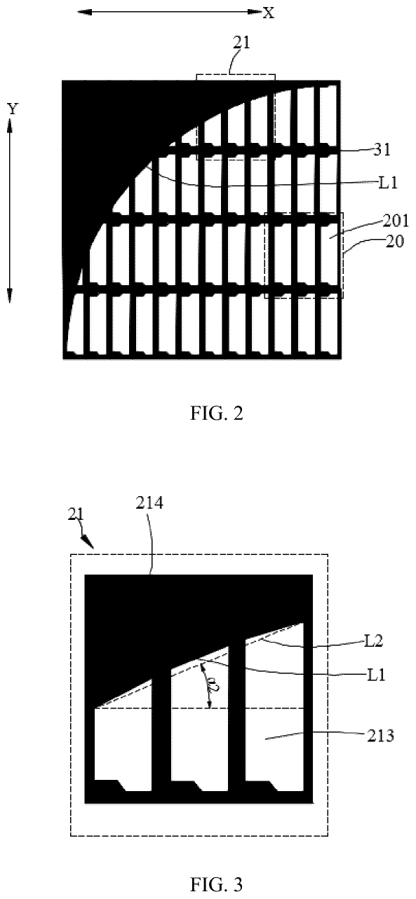

As shown in FIGS. 2, 3, and 4, in some embodiments of the present disclosure, the light-shielding pattern 30 includes a plurality of light-shielding sub-patterns 301 arranged in the first direction X. The light-shielding sub-patterns 301 respectively correspond to the sub-pixels 201 of the edge pixel 21. The light-shielding sub-pattern 301 has a first dividing edge L3, and the first dividing edge L3 divides the sub-pixel 201 into a light-shielding sub-region 211 and a light-transmitting sub-region 212. The first dividing edge L3 has a first angle α1 with respect to the first direction X, and 0≤α1≤90°. The edge L1 of the special-shaped display region 11b intersects with edges of the edge pixel 21 at a first intersection point and a second intersection point, and the line connecting the first intersection point and the second intersection point is a first connecting line L2. The first dividing edge L3 is inclined in a same direction as the first connecting line L2. In the embodiment, the first dividing edge L3 of the light-shielding sub-pattern 301 has the same inclination direction as the first connecting line L2, so that the edge of the light-transmitting region 212 of the edge pixel 21 has a shape approximating that of the edge L1 of the special-shaped display region 11b, thereby further reducing the probability of presence of zigzags on the edge of the special-shaped display region.

It is to be noted herein that the shape and size of the light-shielding sub-pattern 301 corresponding to the sub-pixel 201 in the edge pixel 21 are set in the same way as that of the shape of the light-shielding pattern 30 corresponding to the edge pixel 21 as described above, which will not be repeated in detail herein in the present disclosure.

In some embodiments of the present disclosure, the first connecting line L2 has a second angle α2 with respect to the first direction X. The difference between the first angle α1 and the second angle α2 is not greater than 2°, for example, not greater than 1°, so that the edge of the light-transmitting region 212 of the edge pixel 21 is more similar in shape to the edge L1 of the special-shaped display region 11b.

In a specific embodiment, the first angle α1 and the second angle α2 are equal. In another embodiment, as shown in FIG. 5, the edge L1 of the special-shaped display region 11b has a start point and an end point, and in a direction from the start point to the end point of the edge L1 of the special-shaped display region 11b, a difference between the first angles α1 of the light-shielding sub-patterns 301 of two adjacent edge pixels 21 is b. The number of edge pixels 21 corresponding to the edge L1 of the special-shaped display region 11b is n. The edge L1 of the special-shaped display region 11b has an approximate angle β, the approximate angle β is a central angle of a circular arc when the edge L1 of the special-shaped display region 11b is fitted into the circular arc, and b=β/n. The edge L1 of the special-shaped display region 11b is a curve having a certain curvature.

In yet another embodiment, the edge L1 of the special-shaped display region 11b has a start point and an end point, and in a direction from the start point to the end point of the edge L1 of the special-shaped display region 11b, a difference between the first angles α1 of the light-shielding sub-patterns 301 of two adjacent edge pixels 21 is b, and b=90°/m. m is the number of corresponding edge pixels 21 when the edge L1 of the special-shaped display region 11b is fitted and expanded into a ¼ circular arc. It is to be noted herein that the number of corresponding edge pixels 21 when the edge L1 of the special-shaped display region 11b is fitted and expanded into the ¼ circular arc includes the number of original edge pixels 21 corresponding to the edge L1 of the special-shaped display region 11b and the number of expanded edge pixels 21 corresponding to the segment expanded when the edge L1 of the special-shaped display region 11b is expanded into the ¼ circular arc, and the layout, shape and size of the expanded edge pixels 21 are the same as those of the other pixels 20. When the difference between the first angles α1 of the light-shielding sub-patterns 301 of two adjacent edge pixels 21 is equal, the automated design of the light-shielding pattern 30 may be easily implemented. It is to be noted here that when the edge L1 of the special-shaped display region 11b is fitted and expanded into the ¼ circular arc, at the two endpoints of the circular arc, the first angle α1 of the light-shielding sub-pattern 301 of the edge pixel 21 corresponding to one of the endpoints may be defined as 90°, and then the first angle α1 of the light-shielding sub-pattern 301 of the edge pixel 21 corresponding to the other endpoint is 0°.

As shown in FIG. 4, in some embodiments of the present disclosure, the first angles α1 of the light-shielding sub-patterns 301 corresponding to respective sub-pixels 201 in a single edge pixel 21 are equal. Further, the shape and size of the light-shielding sub-patterns 301 corresponding to respective sub-pixels 201 in a single edge pixel 21 are the same to enhance the display uniformity of the respective sub-pixels 201.

As shown in FIGS. 1, 2, and 4, the present disclosure also provides a manufacturing method of a display panel 10, the display panel 10 includes a display region 11 and a non-display region 12 provided at the periphery of the display region 11, and the display region 11 includes a main display region 11a and a special-shaped display region 11b provided at the periphery of the main display region 11a. The manufacturing method of the display panel 10 includes:
S100, providing a base substrate;
S200, forming a plurality of pixels 20 on a side of the base substrate, the plurality of pixels 20 being provided in the display region, the plurality of pixels 20 including an edge pixel 21b with an orthographic projection on the base substrate overlapped with an orthographic projection of an edge L1 of the special-shaped display region 11b on the base substrate, the edge pixel 21 being provided with a light-shielding pattern 30, the light-shielding pattern 30 dividing the edge pixel 21 into a light-shielding region 211 and a light-transmitting region 212, and the edge pixel 21 having an experimental gray scale;
S300, setting a predetermined gray scale for the edge pixel 21; and
S400, adjusting a size of the light-shielding pattern 30 to change a brightness ratio and the experimental gray scale of the edge pixel 21 such that the experimental gray scale of the edge pixel 21 is equal to the predetermined gray scale of the edge pixel 21.

The brightness ratio is a ratio of a brightness of the light-transmitting region 212 of the edge pixel 21 to a brightness of the edge pixel when an entire region of the edge pixel 21 is light-transmitting, and the experimental gray scale of the edge pixel 21 has an exponential function relationship with the brightness ratio of the edge pixel 21.

In step S200, the experimental gray scale of the edge pixel 21 is a function value of the exponential function, and the brightness ratio of the edge pixel 21 is a base of the exponential function. The experimental gray scale of the edge pixel 21 may change as the brightness ratio of the edge pixel 21 changes, and the brightness ratio of the edge pixel 21 may change as the size of the light-shielding pattern 30 changes.

In some embodiments, the experimental gray scale of the edge pixel 21 satisfies a following relationship with the brightness ratio of the edge pixel 21:

$${Gy}^{′} = k \times {( \frac{M}{N} )}^{( \frac{1}{h} )}$$

where Gy′ is the experimental gray scale of the edge pixel 21, M is the brightness of the light-transmitting region of the edge pixel 21, N is the brightness of the edge pixel 21 when the entire region of the edge pixel 21 is light-transmitting, k is a first constant which may be 255, and h is a gamma value which may be 2.2.

In the present disclosure, the display panel 10 generally includes an array substrate and a color filter substrate provided opposite to each other, and a liquid crystal layer sealed between the array substrate and the color filter substrate. The array substrate includes a base substrate as described above and a driving circuit provided on a side of the base substrate, and the driving circuit is used to drive the deflection of the liquid crystal layer. The color filter substrate includes a substrate and a color filter layer provided on a side of the substrate, and the color filter layer may include a black matrix 31 and a filter film divided by the black matrix 31. Different regions of the filter film may transmit different colors of light, such as red light, green light and blue light. The plurality of pixels 20 of the display panel 10 are also divided by the black matrix 31. The light-shielding pattern 30 may be provided in the same layer as the black matrix 31.

In step S200, both the black matrix 31 and the light-shielding pattern 30 are formed of a light-shielding material, specifically, for example, a light-shielding material layer may be deposited on a side of the substrate, and then the light-shielding material layer may be patterned to form the light-shielding pattern 30 and the black matrix 31. It is to be noted herein that the light-shielding pattern 30 may be designed to satisfy the set conditions for the light-shielding pattern 30 in the present disclosure, such that the experimental gray scale of the edge pixel 21 is equal to the predetermined gray scale of that edge pixel 21, for example.

In step S300, the predetermined gray scale of the edge pixel 21 is set. The predetermined gray scale of the edge pixel 21 is set according to the areas of the regions at both sides of the edge pixel 21 after being divided by the edge of the special-shaped display region, such that the predetermined gray scale of the edge pixel 21 may achieve uniform gray scale transition between the regions at both sides of the edge of the special-shaped display region. As shown in FIG. 3, by way of example, the edge L1 of the special-shaped display region 11b divides a corresponding edge pixel 21 into a display sub-region 213 and a non-display sub-region 214, the area of the entire region of the edge pixel 21 is A0, the area of the display sub-region 213 of the edge pixel 21 is A1, the area of the non-display sub-region 213 of the edge pixel 21 is A2, and A1+A2=A0. Further, the predetermined gray scale of the edge pixel 21 is set according to a ratio of the area A1 of the display sub-region 213 to the area A0 of the entire region of the edge pixel 21. The gray scale represents a brightness level of the pixel 20, and currently, 0˜255 gray scales are generally divided in the display industry by taking an 8 bit Panel as the benchmark, and there are a total of 256 brightness levels. As defined, when A1=A0, the gray scale of the edge pixel 21 is 255, and when A1=0, the gray scale of the edge pixel 21 is 0. In a specific embodiment, the predetermined gray scale of the edge pixel 21 satisfies the following relationship:

$$G y = 255 \times {( \frac{A 1}{A 0} )}^{( \frac{1}{h} )}$$

where Gy is the predetermined gray scale of the edge pixel 21, and h is a gamma value, which generally takes a value of 2.2.

In step S400, the size of the light-shielding pattern 30 is adjusted to change the brightness ratio and the experimental gray scale of the edge pixel 21 such that the experimental gray scale of the edge pixel 21 is equal to the predetermined gray scale of the edge pixel 21.

In this step, the size of the light-shielding pattern 30 may be set by adjusting the size of the light-shielding pattern 30 in a certain direction. In some embodiments of the present disclosure, certain parameters of the shape of the light-shielding pattern 30 may be set first.

As shown in FIGS. 2 to 4, specifically, the light-shielding pattern 30 includes a plurality of light-shielding sub-patterns 301 arranged in the first direction X. The light-shielding sub-patterns 301 respectively correspond to the sub-pixels 201 of the edge pixel 21. The light-shielding sub-pattern 301 has a first dividing edge L3, and the first dividing edge L3 divides the sub-pixel 201 into a light-shielding sub-region 211 and a light-transmitting sub-region 212. The first dividing edge L3 has a first angle α1 with respect to the first direction X, and 0≤α1≤90°. The edge L1 of the special-shaped display region 11b intersects with edges of the edge pixel 21 at a first intersection point and a second intersection point, and the line connecting the first intersection point and the second intersection point is a first connecting line L2. The first dividing edge L3 is inclined in a same direction as the first connecting line L2. The first connecting line L2 has a second angle α2 with respect to the first direction X. The difference between the first angle α1 and the second angle α2 is not greater than 2°, for example, not greater than 1°.

In a specific embodiment, the first angle α1 and the second angle α2 are equal. In another embodiment, as shown in FIG. 5, the edge L1 of the special-shaped display region 11b has a start point and an end point, and in a direction from the start point to the end point of the edge L1 of the special-shaped display region 11b, a difference between the first angles α1 of the light-shielding sub-patterns 301 of two adjacent edge pixels 21 is b. The number of edge pixels 21 corresponding to the edge L1 of the special-shaped display region 11b is n. The edge L1 of the special-shaped display region 11b has an approximate angle β, the approximate angle β is a central angle of a circular arc when the edge L1 of the special-shaped display region 11b is fitted into the circular arc, and b=β/n. The edge L1 of the special-shaped display region 11b is a curve having a certain curvature.

In yet another embodiment, the edge L1 of the special-shaped display region 11b has a start point and an end point, and in a direction from the start point to the end point of the edge L1 of the special-shaped display region 11b, a difference between the first angles α1 of the light-shielding sub-patterns 301 of two adjacent edge pixels 21 is b, and b=90°/m. m is the number of corresponding edge pixels 21 when the edge L1 of the special-shaped display region 11b is fitted and expanded into a ¼ circular arc. It is to be noted herein that the number of corresponding edge pixels 21 when the edge L1 of the special-shaped display region 11b is fitted and expanded into the ¼ circular arc includes the number of original edge pixels 21 corresponding to the edge L1 of the special-shaped display region 11b and the number of expanded edge pixels 21 corresponding to the segment expanded when the edge L1 of the special-shaped display region 11b is expanded into the ¼ circular arc, and the layout, shape and size of the expanded edge pixels 21 are the same as those of the other pixels 20. When the difference between the first angles α1 of the light-shielding sub-patterns 301 of two adjacent edge pixels 21 is equal, the automated design of the light-shielding pattern 30 may be easily implemented. The first angles α1 of the light-shielding sub-patterns 301 corresponding to respective sub-pixels 201 in a single edge pixel 21 are equal. Further, the shapes and sizes of the light-shielding sub-patterns 301 corresponding to respective sub-pixels 201 in a single edge pixel 21 are the same to enhance the display uniformity of the respective sub-pixels 201.

After determining the inclination angle of the first dividing edge L3 of the light-shielding pattern 30, the size of the light-shielding pattern 30 is then determined by adjusting the length of the light-shielding pattern 30 in a certain direction. As shown in FIG. 7, the light-shielding sub-pattern 301 has a design length h in a third direction Z. The third direction Z has a third angle α3 with respect to the first direction X, and the third angle α3 is greater than the first angle α1. The third direction Z may be parallel to the edge of the pixel 20. By adjusting the design length h of the light-shielding sub-pattern 301, the size of the light-shielding sub-pattern 301 is adjusted, which in turn changes the size of the corresponding light-shielding pattern 30.

The present disclosure also provides a display device including a display panel 10, which may be the display panel 10 in any of the above embodiments. The specific structure and beneficial effect of the display panel 10 may be referred to that in the above embodiments of the display panel 10, and will not be repeated here. The display device of the present disclosure may be an electronic device such as a mobile phone, a tablet computer, a television, or the like, and will not be listed herein.

It is to be noted that various steps of the method in the present disclosure are described in the accompanying drawings in a particular order, which however does not require or imply that the steps must be performed in that particular order or that all of the steps shown must be performed in order to achieve the desired result. Additionally or alternatively, some steps may be omitted, a plurality of steps may be combined a single step to be performed, and/or a single step may be divided into a plurality of steps to be performed, and so on, all of which should be considered as part of the present disclosure.

It is to be appreciated that the present disclosure does not limit the application thereof to the detailed structure and arrangement of the components presented herein. The present disclosure may have other embodiments and may be implemented and performed in a variety of ways. The foregoing variant and modified forms fall within the scope of the present disclosure. It is to be understood that the present disclosure, as disclosed and limited in this specification, extends to all alternative combinations of two or more individual features mentioned or apparent in the text and/or in the accompanying drawings. All of these various combinations constitute a plurality of alternative aspects of the present disclosure. The embodiments of this specification illustrate the best ways known for implementing the present disclosure and will enable a person skilled in the art to utilize the present disclosure.

What is claimed is:

1. A display panel, wherein:
the display panel comprises a display region and a non-display region at a periphery of the display region, the display region comprises a main display region and a special-shaped display region at a periphery of the main display region;
the display panel further comprises a base substrate and a plurality of pixels provided on a side of the base substrate, the plurality of pixels are provided in the display region, and the plurality of pixels comprises an edge pixel with an orthographic projection on the base substrate overlapped with an orthographic projection of an edge of the special-shaped display region on the base substrate;
the edge pixel is provided with a light-shielding pattern, and the light-shielding pattern divides the edge pixel into a light-shielding region and a light-transmitting region; and
the edge pixel has a predetermined gray scale and a brightness ratio, the brightness ratio is a ratio of a brightness of the light-transmitting region of the edge pixel to a brightness of the edge pixel when an entire region of the edge pixel is light-transmitting, and the predetermined gray scale of the edge pixel has an exponential function relationship with the brightness ratio of the edge pixel.

2. The display panel according to claim 1, wherein the edge pixel comprises a plurality of sub-pixels spaced apart in a first direction, and the light-shielding pattern comprises a plurality of light-shielding sub-patterns arranged in the first direction and respectively corresponding to the sub-pixels of the edge pixel;
the light-shielding sub-pattern has a first dividing edge, the first dividing edge divides the sub-pixel into a light-shielding sub-region and a light-transmitting sub-region, the first dividing edge has a first angle α1 with respect to the first direction, and 0≤α1≤90°;
the edge of the special-shaped display region intersects with edges of the edge pixel at a first intersection point and a second intersection point, and a line connecting the first intersection point and the second intersection point is a first connecting line; and
the first dividing edge is inclined in a same direction as the first connecting line.

3. The display panel according to claim 2, wherein the first connecting line has a second angle with respect to the first direction, and a difference between the first angle and the second angle is not greater than 2°.

4. The display panel according to claim 3, wherein the first angle and the second angle are equal to each other.

5. The display panel according to claim 2, wherein the edge of the special-shaped display region has a start point and an end point, and in a direction from the start point to the end point of the edge of the special-shaped display region, a difference between the first angles of the light-shielding sub-patterns of two adjacent edge pixels is b;
a number of edge pixels corresponding to the edge of the special-shaped display region is n; and
the edge of the special-shaped display region has an approximate angle β, the approximate angle is a central angle of a circular arc when the edge of the special-shaped display region is fitted into the circular arc, and
b=β/n.

6. The display panel according to claim 2, wherein the edge of the special-shaped display region has a start point and an end point, and in a direction from the start point to the end point of the edge of the special-shaped display region, a difference between the first angles of the light-shielding sub-patterns of two adjacent edge pixels is b, and
b=90°/m
where m is a number of corresponding edge pixels when the edge of the special-shaped display region is fitted and expanded into a ¼ circular arc.

7. The display panel according to claim 2, wherein the first angles of the light-shielding sub-patterns corresponding to respective sub-pixels in a single edge pixel are equal to each other.

8. The display panel according to claim 1, wherein the predetermined gray scale of the edge pixel satisfies a following relationship with the brightness ratio of the edge pixel:
$$G y = k \times {( \frac{M}{N} )}^{( \frac{1}{h} )}$$
where Gy is the predetermined gray scale of the edge pixel, M is the brightness of the light-transmitting region of the edge pixel, N is the brightness of the edge pixel when the entire region of the edge pixel is light-transmitting, k is a first constant, and h is a gamma value.

9. The display panel according to claim 8, wherein k has a value of 255 and h has a value of 2.2.

10. The display panel according to claim 1, wherein the edge of the special-shaped display region divides the edge pixel into a display sub-region and a non-display sub-region, wherein an area of the entire region of the edge pixel is A0, an area of the display sub-region of the edge pixel is A1, an area of the non-display sub-region of the edge pixel is A2, A1+A2=A0, and
$$G y = 255 \times {( \frac{A 1}{A 0} )}^{( \frac{1}{h} )}$$
where Gy is the predetermined gray scale of the edge pixel, and h is a gamma value.

11. A manufacturing method of a display panel, the display panel comprising a display region and a non-display region at a periphery of the display region, the display region comprising a main display region and a special-shaped display region at a periphery of the main display region, wherein the manufacturing method comprises:
providing a base substrate;
forming a plurality of pixels on a side of the base substrate, the plurality of pixels being provided in the display region, the plurality of pixels comprising an edge pixel with an orthographic projection on the base substrate overlapped with an orthographic projection of an edge of the special-shaped display region on the base substrate, the edge pixel being provided with a light-shielding pattern, the light-shielding pattern dividing the edge pixel into a light-shielding region and a light-transmitting region, and the edge pixel having an experimental gray scale;
setting a predetermined gray scale for the edge pixel; and
adjusting a size of the light-shielding pattern to change a brightness ratio and the experimental gray scale of the edge pixel such that the experimental gray scale of the edge pixel is equal to the predetermined gray scale of the edge pixel,
wherein the brightness ratio is a ratio of a brightness of the light-transmitting region of the edge pixel to a brightness of the edge pixel when an entire region of the edge pixel is light-transmitting, and the experimental gray scale of the edge pixel has an exponential function relationship with the brightness ratio of the edge pixel.

12. The manufacturing method according to claim 11, wherein the edge pixel comprises a plurality of sub-pixels spaced apart in a first direction, and the light-shielding pattern comprises a plurality of light-shielding sub-patterns arranged in the first direction and respectively corresponding to the sub-pixels of the edge pixel;
the light-shielding sub-pattern has a first dividing edge, the first dividing edge divides the sub-pixel into a light-shielding sub-region and a light-transmitting sub-region, the first dividing edge has a first angle α1 with respect to the first direction, and 0≤α1≤90°;
the edge of the special-shaped display region intersects with edges of the edge pixel at a first intersection point and a second intersection point, and a line connecting the first intersection point and the second intersection point is a first connecting line; and
the first dividing edge is inclined in a same direction as the first connecting line.

13. The manufacturing method according to claim 12, wherein the first connecting line has a second angle with respect to the first direction, and a difference between the first angle and the second angle is not greater than 2°.

14. The manufacturing method according to claim 13, wherein the first angle and the second angle are equal to each other.

15. The manufacturing method according to claim 12, wherein the edge of the special-shaped display region has a start point and an end point, and in a direction from the start point to the end point of the edge of the special-shaped display region, a difference between the first angles of the light-shielding sub-patterns of two adjacent edge pixels is b;
a number of edge pixels corresponding to the edge of the special-shaped display region is n; and
the edge of the special-shaped display region has an approximate angle β, the approximate angle is a central angle of a circular arc when the edge of the special-shaped display region is fitted into the circular arc, and
$$b = β / n .$$

16. The manufacturing method according to claim 12, wherein the edge of the special-shaped display region has a start point and an end point, and in a direction from the start point to the end point of the edge of the special-shaped display region, a difference between the first angles of the light-shielding sub-patterns of two adjacent edge pixels is b, and
b=90°/m
where m is a number of corresponding edge pixels when the edge of the special-shaped display region is fitted and expanded into a ¼ circular arc.

17. The manufacturing method according to claim 12, wherein the first angles of the light-shielding sub-patterns corresponding to respective sub-pixels in a single edge pixel are equal to each other.

18. The manufacturing method according to claim 12, wherein the light-shielding sub-pattern has a design length in a third direction, the third direction has a third angle with respect to the first direction, and the third angle is greater than the first angle; and
adjusting the size of the light-shielding pattern comprises:
changing the size of the light-shielding pattern by adjusting a design length of the light-shielding sub-pattern to adjust a size of the light-shielding sub-pattern.

19. The manufacturing method according to claim 11, wherein the experimental gray scale of the edge pixel satisfies a following relationship with the brightness ratio of the edge pixel:
$${Gy}^{′} = k \times {( \frac{M}{N} )}^{( \frac{1}{h} )}$$
where Gy′ is the experimental gray scale of the edge pixel, M is the brightness of the light-transmitting region of the edge pixel, N is the brightness of the edge pixel when the entire region of the edge pixel is light-transmitting, k is a first constant, and h is a gamma value.

20. The manufacturing method according to claim 11, wherein the edge of the special-shaped display region divides the edge pixel into a display sub-region and a non-display sub-region, an area of the entire region of the edge pixel is A0, an area of the display sub-region of the edge pixel is A1, an area of the non-display sub-region of the edge pixel is A2, A1+A2=A0, and
$$G y = 255 \times {( \frac{A 1}{A 0} )}^{( \frac{1}{h} )}$$
where Gy is the predetermined gray scale of the edge pixel, and h is a gamma value.
